(19) United States
(12) Patent Application Publication
(10) Pub. No.: US 2008/0257254 A1
(43) Pub. Date: Oct. 23, 2008

(54) LARGE GRAIN, MULTI-CRYSTALLINE SEMICONDUCTOR INGOT FORMATION METHOD AND SYSTEM

(76) Inventors: Dieter Linke, Berlin (DE); Matthias Heuer, Leipzig (DE); Fritz Kirscht, Berlin (DE); Jean Patrice Rakotoniana, Berlin (DE); Kamel Ounadjela, Belmont, CA (US)

Correspondence Address: HULSEY IP INTELLECTUAL PROPERTY LAWYERS, P.C., 919 Congress Avenue, Suite 919, AUSTIN, TX, 78701, US

(21) Appl. No.: 11/736,390

(22) Filed: Apr. 17, 2007

(51) Int. Cl. C30B 15/20

(52) U.S. Cl. 117/15; 117/202

(57) ABSTRACT

Techniques for the formation of a large grain, multi-crystalline semiconductor ingot and include forming a silicon melt in a crucible, the crucible capable of locally controlling thermal gradients within the silicon melt. The local control of thermal gradients preferentially forms silicon crystals in predetermined regions within the silicon melt by locally reducing temperatures is the predetermined regions. The method and system control the rate at which the silicon crystals form using local control of thermal gradients for inducing the silicon crystals to obtain preferentially maximal sizes and, thereby, reducing the number of grains for a given volume. The process continues the thermal gradient control and the rate control step to form a multicrystalline silicon ingot having reduced numbers of grains for a given volume of the silicon ingot.

### FIELD

The present disclosure relates to methods and systems for use in the fabrication of semiconductor materials such as silicon. More particularly, the present disclosure relates to large grain, multi-crystalline semiconductor ingot formation method and system for producing a high purity semiconductor ingot.

### DESCRIPTION OF THE RELATED ART

The photovoltaic industry (PV) industry is growing rapidly and is responsible for increasing industrial consumption of silicon being consumed beyond the more traditional integrated circuit (IC) applications. Today, the silicon needs of the solar cell industry are starting to compete with the silicon needs of the IC industry. With present manufacturing technologies, both integrated circuit (IC) and solar cell industries require a refined, purified, silicon feedstock as a starting material.

Materials alternatives for solar cells range from single-crystal, electronic-grade (EG) silicon to relatively dirty, metallurgical-grade (MG) silicon. EG silicon yields solar cells having efficiencies close to the theoretical limit, but at a prohibitive price. On the other hand, MG silicon typically fails to produce working solar cells. Early solar cells using polycrystalline silicon achieved relatively low efficiencies of approximately 6%. In this context, efficiency is a measure of the fraction of the energy incident upon the cell to that collected and converted into electric current. However, there may be other semiconductor materials that could be useful for solar cell fabrication. In practice, however, nearly 90% of commercial solar cells are made of crystalline silicon.

Today's commercially available solar cells may achieve efficiencies near 24%. However, these solar cells require high purity materials and improved processing techniques. These engineering advances have helped the industry approach the theoretical limit for single junction silicon solar cell efficiencies of 31%. Still, known processes demand the very highest purity silicon feedstock.

Because of the high cost and complex processing requirements of obtaining and using highly pure silicon feedstock and the competing demand from the IC industry, silicon needs usable for solar cells are not likely to be satisfied by either EG, MG, or other silicon producers using known processing techniques. As long as this unsatisfactory situation persists, economical solar cells for large-scale electrical energy production may not be attainable.

Accordingly, a need exists for a source of silicon ingots to meet the silicon needs of the solar cell industry, which source may not compete with the demands of the IC industry.

Several factors determine the quality of raw silicon material that may be useful for solar cell fabrication. One particularly important aspect of raw silicon material is the size of the silicon grains in a multicrystalline material. In supplying the needed multicrystalline silicon ingots for use in forming multicrystalline silicon wafers usable in solar cells, it is desired that the crystal grain sizes be as large as possible. Large grain size enhances the electrical properties of the later manufactured solar cells, made by this material. A need exists, therefore, for providing multicrystalline silicon ingots that may ultimately form commercially available solar cells with large grain sizes and resulting efficiencies that may be presently achievable using expensive higher purity materials and/or costly processing techniques.

### SUMMARY

Techniques are here disclosed for providing a combination of interrelated steps at the ingot formation level for ultimately making economically viable the fabrication of solar cells on a mass production level. The present disclosure includes a method and system for forming multicrystalline silicon ingots, which ingots include large grain sizes. With the disclosed process and system silicon ingots may formed directly within a silicon melt crucible. The disclosed process forms a large-grain multi-crystalline ingot from molten silicon by precisely controlling local crystallization temperatures throughout a process crucible. The process operates on the molten silicon and uses the driving force inherent to the transition from the liquid state to the solid state as the force which drives the grain growth process. For example, using multicrystalline silicon ingots formed from the processes here disclosed, solar wafers and solar cells, based on this multicrystalline material, with improved performance/cost ratio are practical. In addition, the present disclosure may readily and efficiently combine with metal-related defect engineering at the wafer level to yield a highly efficient PV solar cell.

According to one aspect of the disclosed subject matter, a semiconductor ingot forming method and associated system are provided for large grain, multi-crystalline semiconductor ingot formation. The disclosed method and system include forming a silicon melt in an especially shaped crucible (e.g., a reverse pyramid or reverse conus). The crucible allows locally controlling thermal gradients within the silicon melt. Using these especially shaped crucibles in combination with a corresponding temperature field/profile and temperature gradient the number of seeds for heterogeneous nucleation can be minimized and localized in desired area. The local control of thermal gradients preferentially forms silicon crystal grains that are large in size and small in number in the beginning of solidification occurs in predetermined regions within the silicon melt by locally reducing temperatures in the predetermined regions. The process continues the thermal gradient control and the rate control step to form a multicrystalline silicon ingot having reduced numbers of grains for a given volume of the silicon ingot.

These and other advantages of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages be included within this description, be within the scope of the accompanying claims.

### BRIEF DESCRIPTIONS OF THE DRAWINGS

The features, nature, and advantages of the disclosed subject matter may become more apparent from the detailed description set forth below when taken in conjunction with the drawings in which like reference characters identify correspondingly throughout and wherein:

FIG. 1 is a prior art diagram of a known Czochralski monocrystalline silicon ingot formation process;

FIG. 2 illustrates conceptually an embodiment of the presently disclosed system for fabricating a multicrystalline semiconductor ingot having large grains;

FIG. 3 shows in further detail the crucible and associated gas/electrical temperature control system of the semiconductor ingot fabrication system of FIG. 2;

FIG. 4 depicts an exemplary array of an inert gas-based crucible temperature regulation system for operation with the semiconductor ingot formation system of FIG. 2;

FIGS. 5 through 9 provide alternative constructions of a semiconductor ingot formation system for employing the various novel teachings of the disclosed subject matter; and

FIG. 10 shows an embodiment for a direct solidification of a silicon melt using a seed crystal to get a monocrystalline silicon ingot or a multicrystalline ingot with large grain sizes and a lower number of grains for a given volume.

### DETAILED DESCRIPTION OF THE SPECIFIC EMBODIMENTS

The method and system of the present disclosure provide a semiconductor ingot formation process for producing a large-grained, multi-crystalline semiconductor (e.g., silicon) ingot. As a result of using the disclosed subject matter, an improvement in the properties of low-grade semiconductor materials, such as upgraded metallurgical grade silicon (UMG) occurs. Such improvement allows use of UMG silicon, for example, in producing solar cells as may be used in solar power generation and related uses. The method and system of the present disclosure, moreover, particularly benefits the formation of semiconductor solar cells using UMG or other non-electronic grade semiconductor materials, but can be used for electronic grade material too. The present disclosure may allow the formation of solar cells in greater quantities and in a greater number of fabrication facilities than has heretofore been possible.

Among various technical advantages and achievements herein described, certain ones of particular note include the ability to reduce the adverse effects of small grain size, multi-crystalline silicon ingots, which exhibit less than desirable electron carrier lifetimes when such silicon may be used for solar cells.

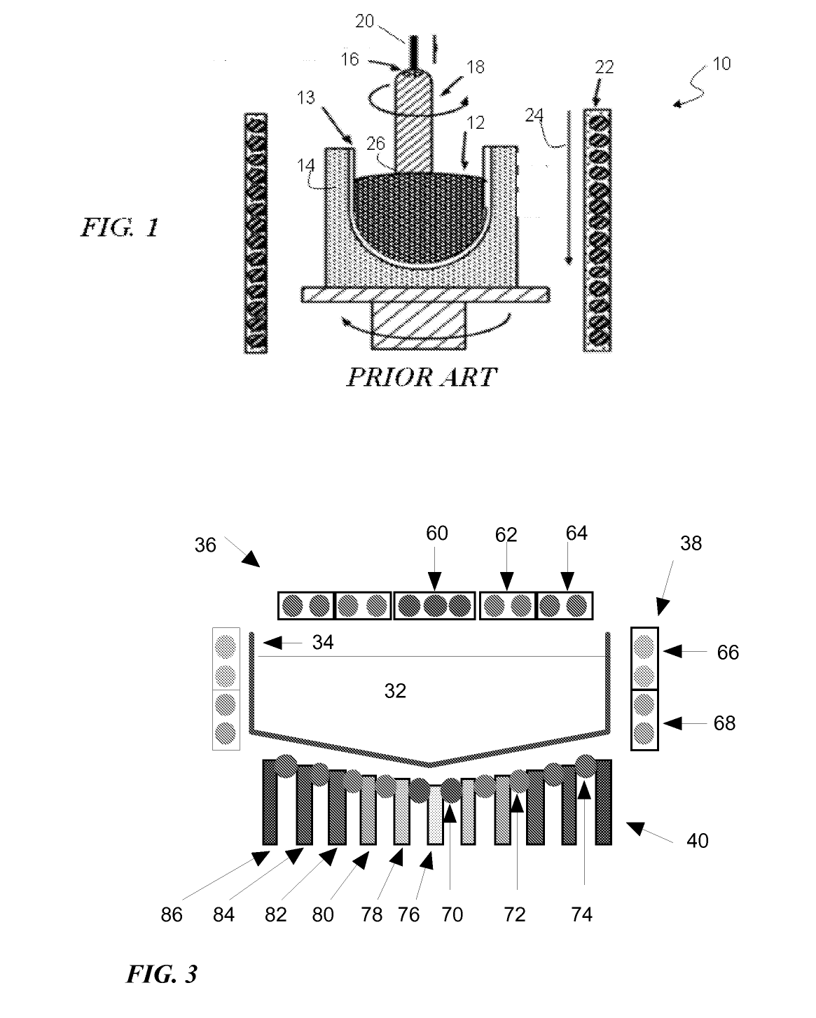

To distinguish the present disclosure from known semiconductor ingot formation process, FIG. 1 presents a prior art diagram of a known Czochralski (CZ) silicon ingot formation process 10. According to the known CZ silicon formation process 10, molten silicon 12 is held in fused silica liner 13 of crucible 14. Seed crystal 16 is inserted and then pulled from molten silicon melt 12 to form silicon ingot 18. Thus, as seed crystal 16, which is attached to puller rod 20, moves in the upward direction, silicon ingot 18 grows. Heater system 22 provides process control heating so as to create a temperature gradient 24. Temperature gradient 24 results in higher temperatures nearer the bottom of crucible 14 for maintaining silicon melt 12, while controlling the seed-melt interface 26.

The CZ process to grow single crystal silicon, therefore, involves melting the silicon in crucible 13, and then inserting seed crystal 16 on puller rod 20, which continuously rotates upon being slowly removed from melt 12. If the temperature gradient 24 of melt 12 is adjusted so that the melting/freezing temperature is just at seed-melt interface 26, a continuous single crystal silicon ingot 18 grows as puller rod 20 moves upward.

The entire apparatus must be enclosed in an argon or helium atmosphere to prevent oxygen from getting into either melt 12 or silicon ingot 18. Puller rod 20 and crucible 14 are rotated in opposite directions to minimize the effects of convection in the melt. The pull-rate, the rotation rate and temperature gradient 24 must all be carefully optimized for a particular wafer diameter and growth direction.

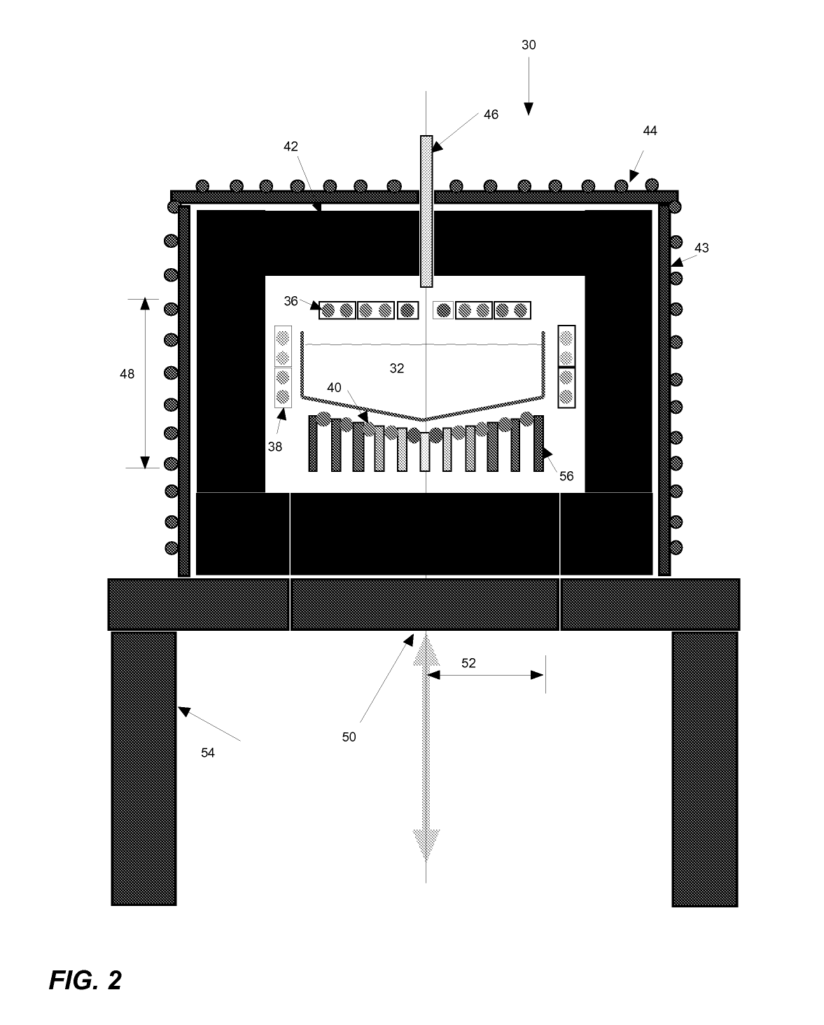

FIG. 2, in contrast, illustrates one embodiment of a process environment 30 for achieving the results of the present disclosure, i.e., a large grain size, multi-crystalline semiconductor ingot. Process environment 30 uses a combination of temperature control gas (for cooling), electrical heating and an especially shaped crucible (reverse pyramid or reverse conus shaped bottom part of the crucible 34) to achieve a localized and controlled crystallization of silicon from silicon melt 32 in defined areas of the crucible 34. Thus, FIG. 3 shows molten silicon 32 partially fills crucible 34. Although no silicon seed crystal appears in silicon melt 32, use of a seed crystal may be employed for initiating a directional solidification silicon crystal formation. Due to the temperature field, temperature profile and the shape of the crucible 34 the heterogeneous nucleation starts in the tip of the reverse pyramid or conus shaped bottom of the crucible 34. Heating zones 36, 38, 40 surround the sides, the top and the bottom of crucible 34. CBCF-isolation chamber 42 further establishes a process environment with crucible 34 for temperature and process atmosphere control. Water cooling system 44 surrounds the stainless steel vessel 43, which camera or pyrometer 46 may penetrate to allow observation or temperature measurement of molten silicon 32, respectively. Crucible 34 has a height 48 and a radius 52 in case of a reverse conus shaped crucible or side length in case of a reverse pyramid shaped crucible, respectively. The relation between these two values is called “aspect ratio”. Certain values of aspect ratio can be used in the present disclosure. For loading and removal of the crucible 34 or/and the solidified crystal, dropping mechanism 50 may move vertically downward within lower frame 54.

Water-cooled, induction or resistivity-heated, processing environment 30 provides a sealed growth chamber having a vacuum of, for example, below 1×10⁻³ Torr and cycle purged with argon or helium to 10 psig several times to expel any oxygen or other gases remaining in the chamber. Heating zones 36, 38, and 40 may be heated by a multi-turn induction coil in a parallel circuit with a tuning capacitor bank, but may consist of resistivity heating elements instead of the induction coils.

Now, the disclosed multicrystalline semiconductor ingot processing environment 30 further includes argon or helium cooling gas system 56, which in the embodiment of FIG. 2, may be interspaced within the associated heating elements of induction or resistivity heating region 40, for example. Cooling gas system 56 provides both more rapid and more controlled cooling of specific regions of the crucible 34 of molten silicon 32. Certain control features of cooling gas system 56 are described in more detail below in association with FIG. 3.

Crucible 34 has a particularly unique shape (reverse pyramid or reverse conus) and the arrangement of heating elements 36, 38, and 40, together with gas cooling pipes 56, allow lowering the rate of heterogeneous nucleation starting from the tip of the bottom of the crucible. In one embodiment, crucible 34 assumes a reverse pyramid shape. Another embodiment exhibits a reverse conus. Irrespective of the particular shape, the present disclosure provides a crucible of a shape that allows for the formation of a process control region wherein temperature control may be localized and silicon crystallization may initially occur.

Process environment 30, therefore, enables production of a multi-crystalline silicon ingot with a low number of large grains, even without the use of a Si seed crystal. Within process environment 30, silicon melt 32 may be cooled-beginning from the center of the bottom of the crucible 34 using an argon or helium gas flow in cooling gas system 56 operating in conjunction with heating elements 40.

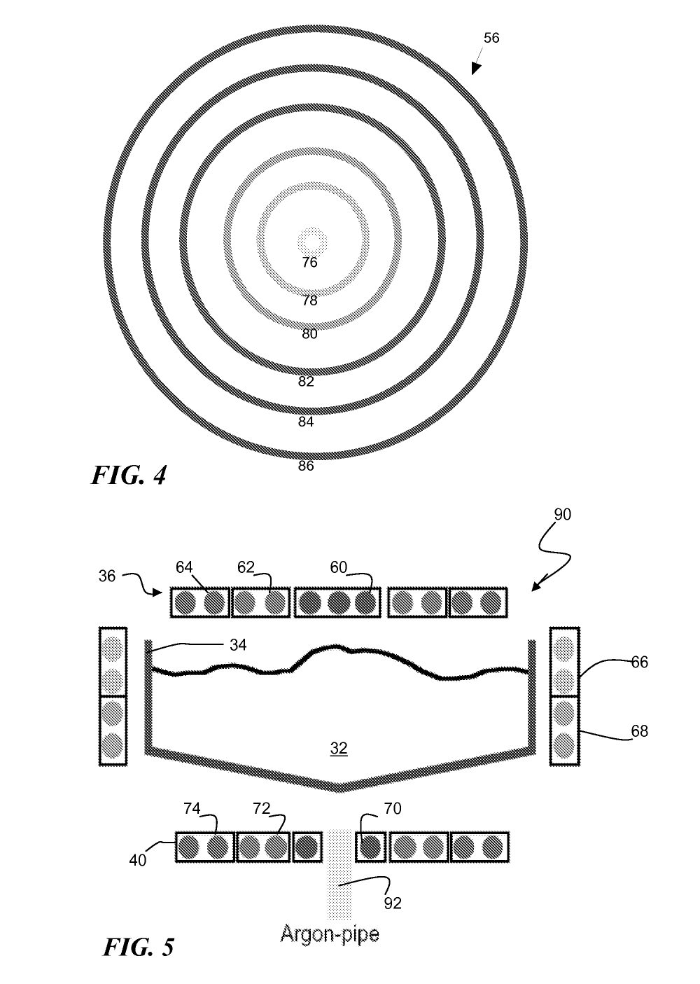

FIGS. 3 and 4 provide a more detailed view of the associated heating elements 36, 38, and 40 for a reverse conus shaped crucible 34 for example, together with cooling gas system 56 for carefully and precisely adjusting temperatures within crucible 34 for creating desired crystallization regions within silicon melt 32. Referring to FIG. 3, heating element 36 may include an innermost set of heaters 60, a middle set of heaters 62, and an outermost set of heaters 64 for controlling the temperature and mixing of the uppermost portion of silicon melt 32. Heating element 38 may surround crucible 34 and include heaters 66 and 68. Heaters 66 and 68 therefore may provide axial control of silicon melt 32 temperature. The combination of all heating elements and a aligned temperature regime allows a special crystallization process, called Vertical Gradient Freeze (VGF). As a result of the heaters 60 through 64 operating in association with heaters 66 and 68, a first order of temperature control for silicon melt 32 is possible.

In addition to heating elements 36 and 38, more precise silicon melt 32 and solidification process control is possible through the coordinated operation of heating and cooling element 40, cooling gas system 56 and crucible 34 shape. In particular, heating and cooling element 40 may include an innermost set of heaters 70, a middle set of heaters 72, and an outermost set of heaters 74. Cooling gas system 56 may include innermost cooling gas segments 76, 78, 80, 82, 84 and 86, arranged as concentric rings in case of a reverse conus shaped crucible (see FIG. 4). The responsiveness of cooling gas system, including cooling gas segments 76, 78, 80, 82, 84 and 86 and heating elements 36, 38, and 40 conjoin in a thermal gradient management system capable of carefully and precisely controlling the crystallization of silicon melt 32. In the case of a reverse pyramid shaped crucible the heating system must be aligned accordingly.

FIG. 4 shows that, in case of a cylindrical crucible 34, cooling gas system 56, may form argon or helium pipes arrayed as concentric rings. Due to the possible segmentation of cooling gas system 56, separate temperatures may be achieved in different regions 76, 78, 80, 82, 84 and 86.

Different crucible 34 shapes are possible as well as heating element arrangements, all within the scope of the present disclosure. For example, in case of a quadratic shape of the base of the crucible 34, cooling gas system 56 may have a quadratic shape. Thus, considerations for the arrangement of heating elements and associated cooling gas systems may be determined according to the optimal effects on crystallization of silicon melt 32, starting from the center of the bottom of the unique shaped crucible 34.

In furtherance of the various objectives FIGS. 5 through 8 show illustrative examples of various crucible shapes and process control environment within the scope of the presently disclosed subject matter. Thus, FIG. 5 shows process environment 90, wherein crucible 34 holds silicon melt 32. As with the above-described embodiment, process environment 90 includes heating elements 36, 38, and 40. Heating element 36 provides heaters 60, 62, and 64, heating element provides heaters 66 and 68, heating element 40 provides heaters 70, 72, and 74. In distinction from the process environment of FIGS. 3 and 4, process environment 90 uses a single argon or helium pipe 92 as the cooling gas system. Thus, while specific regional control cooling gas system 56, as appearing in FIG. 4, may not be provided, a degree of simplicity occurs. In other words, a trade-off between the simplicity of a single argon or helium pipe 92, on one hand, and the segment control of a concentric set of pipes in cooling gas system 56 may occur, depending on the demands for process control.

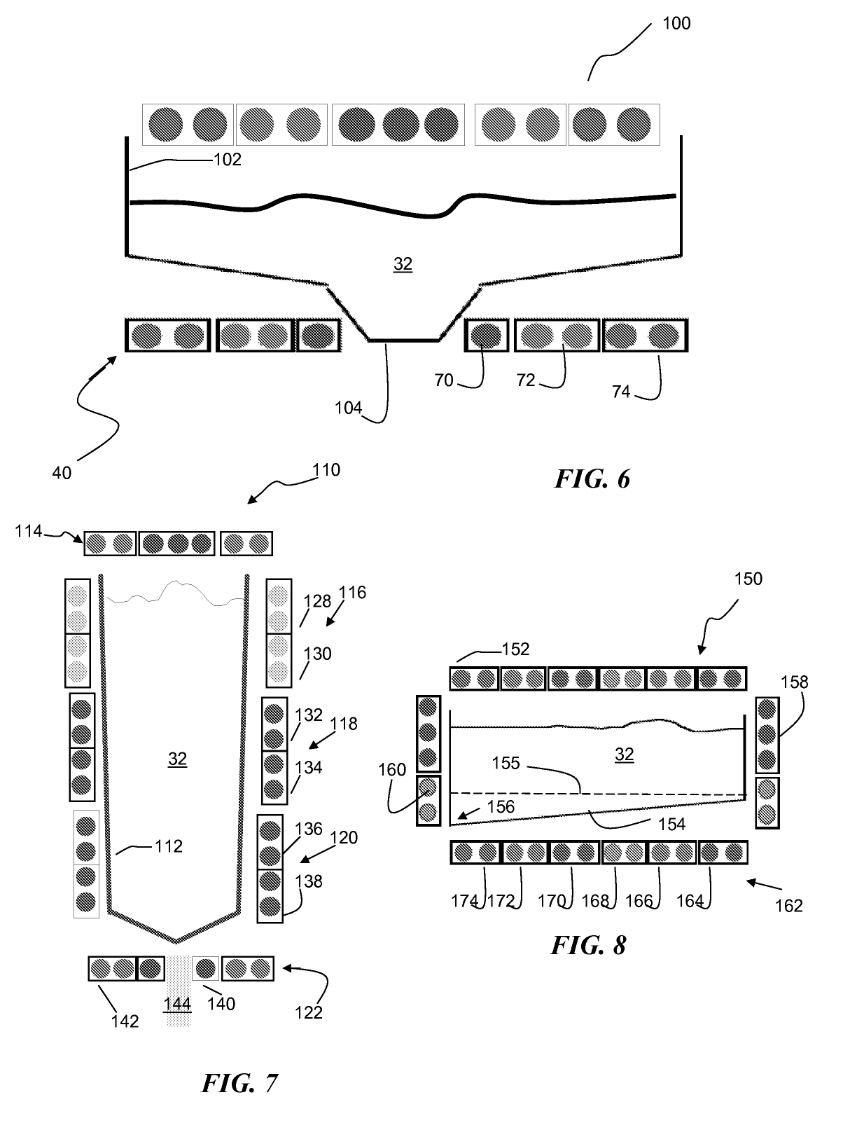

FIG. 6 shows yet a further embodiment of the present disclosure as process environment 100. Within process environment 100, modified crucible 102 holds molten silicon 32 and includes crucible lower region 104 (frustum of a pyramid or frustum of a conus). Also, in distinction from the process environments of FIG. 3 through 5, process environment 100 does not include a cooling gas system, but can include a cooling gas system too as shown in FIGS. 2, 3, 4, 5 and 7. In contrast to FIGS. 2, 3 and 5 the crucible shape is modified. Lower region 104 in combination with the heating environment allows starting solidification only in this region. The result becomes a special shape and adapted heater arrangement reducing the rate of heterogeneous nucleation from the bottom of crucible 102.

FIG. 7 presents a further embodiment of the present disclosure with process environment 110. Process environment 110 uses modified crucible 112, which is elongated vertically as compared to crucible 34 of FIG. 3, for example. For local thermal gradient control, process environment 110 employs a radially smaller upper heating element 114 and lower heating element 122. Conversely, because of the elongation of crucible 112, process environment 110 uses a three-element circumferential heating element including upper heater set 116, middle heater set 118, and lower heater set 120. Heaters for the heating elements 114, 116, 118, 120, and 122 of process environment 110 include inner heaters 124 and outer heaters 126 for upper heating element 114, heaters 128 and 130 for upper heater set 116, heaters 132 and 134 for middle heater set 118, and heaters 136 and 138 for lower heater set 120. Lower heating element 122 further includes inner heater 136 and outer heater 138.

In process environment 110, argon or helium pipe 140 provides the desired cooling gas for local thermal gradient control to allow, that solidification starts in the center of the bottom of crucible 112. The embodiment 110 allows a non-recurring or repeated zone melting process, starting from bottom to top. However, as with the process environment 30 of FIGS. 3 and 4, a set of concentric cooling gas pipes, such as cooling gas system 56 may also find beneficial application within process environment 110 of FIG. 7. Embodiment 110 can include side and top heating elements too, as shown in FIGS. 2, 3, 5, 7 and 8, aligned on the used crucible shape and the process environment. Aligned to the size of the crucible and the process environment more heating elements as shown in FIG. 7 are possible. Depending on the shape of the bottom of the crucible (quadratic, circular) heating arrangement and cooling gas system arrangement will be aligned accordingly.

FIG. 8 shows yet a further embodiment of the present disclosed subject matter, wherein process environment 150 includes a further modified crucible 152. Crucible 152 has a quadratic base 154, which is slanted below dashed line 155 in direction of one corner of the base. Slanted base 154 produces a local region 156 wherein more refined thermal gradient control is possible. Within such local region 156, silicon crystallization starts in this desired area 156 and may be more carefully and fully controlled by adjusting locally the temperature of molten silicon 32. Thus, heating elements 158 and 160 may surround modified crucible 152 to generally control silicon melt 32 temperature and can be used for the crystallization process control. Thus, here, too, there exists local silicon melt 32 thermal gradient control, yet without the use of a cooling gas system, but can include a cooling gas system too as shown in FIGS. 2,3,4, 5 and 7, aligned on the used crucible shape and the process environment. Depending on the outer shape of the crucible (quadratic, circular or other) heating arrangement and cooling gas system arrangement will be aligned accordingly.

As with the above-described process environments, process environment 150 may include a set of lower heating elements 162. Lower heating elements 162 may include individually controllable heaters 164 through 174 for managing temperatures, mixing and solidification of silicon melt 32, while accommodating the various control features and concerns relating to the non-symmetrical nature of modified crucible 152. Embodiment 150 may include upper heating elements as shown in FIGS. 2, 3, 5 and 7, aligned on the crucible shape and the process environment.

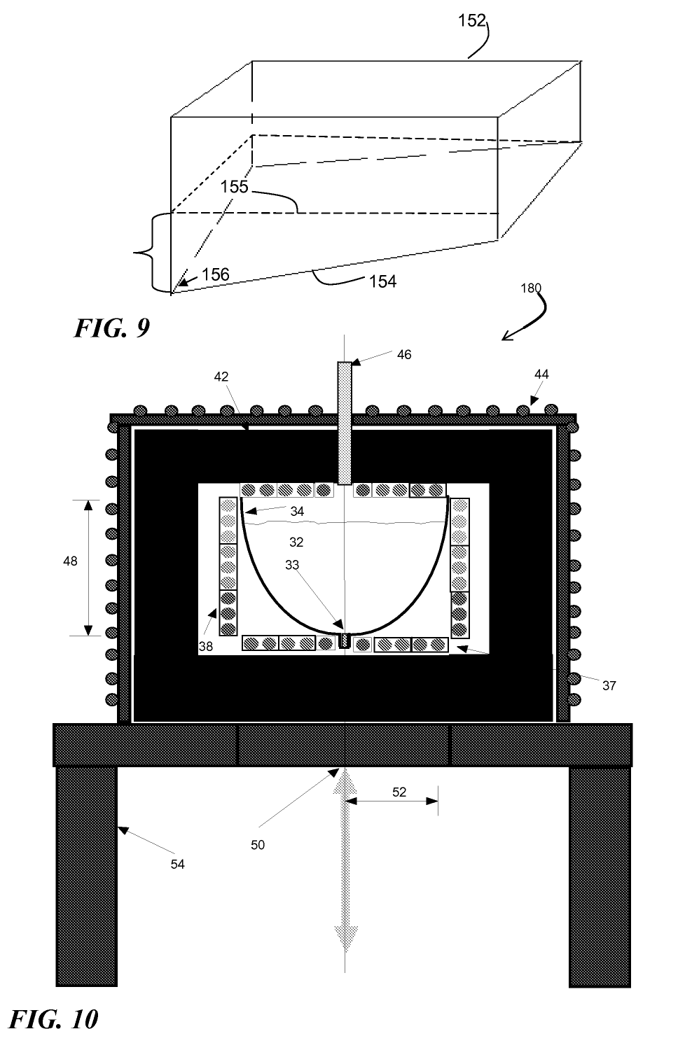

For a more clear view of modified 152, FIG. 9 shows an isometric perspective wherein below line or plane 155 appears slanted bottom 154. Bottom 154, due to the slant forms a process control volume 156 wherein silicon crystallization may initially occur. Heating element 160, therefore, provides process temperature control for process control volume 156. Within process control volume 156 silicon crystallization may initially occur, and in a more controlled manner than may occur throughout crucible 152. The more controlled process volume 156 affords the ability to form silicon crystals having larger grain sizes. Once initially formed, further precise process control may take place through the use of heater element 158 for maintain the growth pattern already occurring within process control volume 156. Thus, through coordinated control of heating elements 158 and 160 in modified crucible 152, the remainder of molten silicon 32 may be formed into crystalline silicon having the desired large grain sizes.

FIG. 10 shows an embodiment 180 for a direct solidification of a silicon melt using a seed crystal to get a monocrystalline silicon ingot or a multicrystalline ingot with large grain sizes and a lower number of grains for a given volume. In particular, seed crystal 33 may be positioned at the bottom of crucible 34, which may include all of the various forms and shapes of crucibles herein disclosed. Moreover, using the local and precise silicon crystallization techniques here disclosed, the combination of a seed crystal may further enhance the growth of large grain sizes and, consequently, is within the scope of the present disclosure.

The present disclosure, therefore, provides a multi-crystalline silicon ingot with a preferably low number of big grains. Using the presently disclosed fabrication system, silicon melt 32 may be cooled-beginning from the center of crucible 34—using an Argon or helium flow and the programmably controlled heating elements 40. This translates the thermal gradient which is generated by sideways arranged heating element 38 and top heating element 36. In case of a cylindrical crucible 34 the heating zones can be arranged as concentric rings whereby in the schematic drawings a particular color corresponds with a particular temperature. This arrangement can be aligned to the angle of the reversed conus shaped bottom of the crucible as shown in FIG. 2 and FIG. 3.

In case of a quadratic crucible such as crucible 152 of FIGS. 8 and 9 the heating zones accordingly may assume a quadratic shape. Different crucible shapes are possible as well as heater arrangements. Furthermore, one has to consider the growth of single crystals. Crucible with special shape and adapted heater arrangement lower the rate of heterogeneous nucleation starting from the bottom of the crucible.

Additionally the construction in FIG. 7 allows a combination of directional solidification with float zone growth. The melt is cooled—beginning from the center of the crucible—using an Argon or helium flow and the programmably controlled heating zones in the bottom. This translates the thermal gradient which is generated by the sideways arranged heaters and the top heaters. After solidification there is the possibility of directly continuing the process with a float zone technique.

In case of a cylindrical crucible the heating zones are concentric rings whereby in the schematic drawings a particular color corresponds with a particular temperature. In case of a quadratic crucible the heating zones accordingly have a quadratic shape. Different crucible shapes are possible as well as heater arrangements. Furthermore one has to consider the growth of single crystals.

The processing features and functions described herein provide for large grain, multi-crystalline semiconductor ingot formation. Although various embodiments which incorporate the teachings of the present disclosure have been shown and described in detail herein, those skilled in the art may readily devise many other varied embodiments that still incorporate these teachings. The foregoing description of the preferred embodiments, therefore, is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein, but is to be accorded the widest scope consistent with the principles and novel features disclosed herein.

What is claimed is:

1. A method for forming a large grain, multi-crystalline semiconductor ingot formation method and system, comprising the steps of:
forming a silicon melt in a crucible;
locally controlling thermal gradients within said silicon melt for preferentially forming silicon crystals in predetermined regions within said silicon melt by locally reducing temperatures is said predetermined regions; and
controlling the rate at which said silicon crystals form using said local control of thermal gradients, thereby inducing said silicon crystals to obtain preferentially maximal sizes and, thereby, reducing the number of grains for a given volume; and
continuing said thermal gradient controlling step and said rate controlling step to form a multicrystalline silicon ingot having reduced numbers of grains for a given volume of the silicon ingot.

2. The method of claim 1, wherein said silicon melt forming step further comprises the step of forming said silicon melt at a temperature of approximately 1450° C.

3. The method of claim 1, wherein said silicon crystals comprise a monocrystalline silicon formation.

4. The method of claim 1, further comprising the step of directly solidifying the silicon melt using a seed crystal.

5. The method of claim 1, wherein said thermal gradient forming step further comprises the step of controlling thermal gradients within said silicon melt using a heating control system for heating said crucible in locally controlling heating of said silicon melt.

6. The method of claim 5, further comprising the step of associating a cooling gas control system with said crucible and said heating control system for locally controlling the cooling of said silicon melt.

7. The method of claim 5, wherein said rate controlling step further comprises the step of controlling the rate of using said gas cooling system in association with said heating control system.

8. The method of claim 6, wherein said rate controlling step further comprises the step of controlling the rate of using said heating control system.

9. The method of claim 5, wherein said rate controlling step further comprises the step of controlling the rate of using said heating control system, said heating control system comprising a plurality of separably controllable heaters.

10. The method of claim 6, wherein said rate controlling step further comprises the step of associating a cooling gas control system with said crucible and said heating control system for locally controlling the cooling of said silicon melt, said cooling gas control system comprising at least one inert gas pathway for directing inert cooling gas to predetermined regions of said crucible.

11. The method of claim 10, wherein said inert gas comprises a gas from the group consisting essentially of argon, helium, or another inert gas.

12. The method of claim 6, wherein said rate controlling step further comprises the step of associating a cooling gas system with said crucible and said heating control system for locally controlling the cooling of said silicon melt, said cooling gas control system using a concentric array of gas pathways for controllably directing argon or helium cooling gas to separate predetermined regions of said crucible.

13. The method of claim 1, wherein said step of forming a silicon melt in a crucible further comprises the step of forming the silicon melt within a cylindrical crucible, said cylindrical crucible comprising a region wherein silicon crystallization may be initially formed using separably controllable ones of said heating elements.

14. The method of claim 12, further comprising the step of forming the silicon melt within a locally depressed region of said cylindrical crucible, said locally depressed region associated with a heating arrangement differing from the remaining portion of said cylindrical crucible.

15. The method of claim 12, wherein said step of forming a silicon melt in a crucible further comprises the step of forming the silicon melt within a cylindrical crucible, said cylindrical crucible comprising height of at least approximately twice the width of the bottom of said cylindrical crucible.

16. The method of claim 1, wherein said step of forming a silicon melt in a crucible further comprises the step of forming the silicon melt within a quadratic crucible, said quadratic crucible comprising a region wherein silicon crystallization may be initially formed using separably controllable ones of said heating elements.

17. A crucible for use in a silicon ingot forming system, said crucible for forming a large grain, multi-crystalline semiconductor ingot and comprising:
a volume for holding a silicon melt in a crucible;
an outer surface for associating with a locally controllable heat sources, said locally controllable heat source for forming thermal gradients within said silicon melt for preferentially forming silicon crystals in predetermined regions within said silicon melt by locally reducing temperatures is said predetermined regions; and
said volume comprising at least one region wherein the rate at which said silicon crystals form may vary according to the controlled presence of thermal gradients; and
a crucible wall comprising a material for transmitting to said silicon melt changes in the heat generated by said controllable heat sources for controlling thermal gradients within said volume and, thereby, controlling the formation the silicon ingot to yield large silicon grains.

18. The crucible of claim 17, wherein said crucible comprises a material for forming said silicon melt at a temperature of approximately 1450° C.

19. The crucible of claim 17, wherein volume comprises a shape for forming a monocrystalline silicon ingot.

20. The crucible of claim 17, wherein said an outer surface for associates with a heating control system for heating said crucible by locally controlling heating of said silicon melt.

21. The crucible of claim 20, wherein said outer surface associates with a cooling gas control system and said heating control system for locally controlling the cooling of said silicon melt.

22. The crucible of claim 21, wherein said outer surface comprises a material for cooperatively responding to temperature gradient control from said cooling gas system and said heating control system.

23. The crucible of claim 21, further comprising a silicon crystallization volume for separable control of silicon crystallization using said cooling gas system and said heating control system.

24. The crucible of claim 21, wherein said outer surface further associates with said cooling gas control system, said cooling gas control system comprising at least one argon or helium gas pathway for directing argon or helium cooling gas to predetermined regions of said outer surface.

25. The crucible of claim 21, wherein said outer surface further associates with said cooling gas system, for locally controlling the cooling of said silicon melt, said cooling gas control system comprising a concentric array of gas pathways for controllably directing argon or helium cooling gas to separate predetermined regions of said crucible.

26. The crucible of claim 17, wherein volume comprises an essentially cylindrical volume, said cylindrical volume comprising a region wherein silicon crystallization may be initially formed using separably controllable ones of said heating elements.

27. The crucible of claim 25, wherein volume comprises an essentially cylindrical volume, said cylindrical volume comprising a locally depressed region of said cylindrical crucible, said locally depressed region associated with a heating arrangement differing from the remaining portion of said essentially cylindrical volume.

28. The crucible of claim 25, wherein volume comprises an essentially cylindrical volume, said essentially cylindrical volume comprising a height of at least approximately twice the width of the bottom of said essentially cylindrical volume.

29. The crucible of claim 17, wherein volume comprises an essentially quadratic volume, said quadratic crucible comprising a region wherein silicon crystallization may be initially formed using separably controllable ones of said heating elements.

30. A system for forming a large grain, multi-crystalline semiconductor ingot formation method and system, comprising the steps of:
a crucible for containing a silicon melt;
at least one heating element for forming a silicon melt in said crucible;
means for locally controlling thermal gradients within said silicon melt for preferentially forming silicon crystals in predetermined regions within said silicon melt by locally reducing temperatures is said predetermined regions; and
means for controlling the rate at which said silicon crystals form using said local control of thermal gradients, thereby inducing said silicon crystals to obtain preferentially maximal sizes and, thereby, reducing the number of grains for a given volume; and
means for continuing to control said thermal gradient controlling means and said rate controlling means for forming a multicrystalline silicon ingot having reduced numbers of grains for a given volume of the silicon ingot.

31. The system of claim 30, wherein said silicon melt forming means further means for forming said silicon melt at a temperature of approximately 1450° C.

32. The system of claim 30, wherein said silicon crystals comprise a monocrystalline silicon formation.

33. The system of claim 30, wherein said thermal gradient forming means further comprises means for controlling thermal gradients within said silicon melt using a heating control system for heating said crucible in locally controlling heating of said silicon melt.

34. The system of claim 33, further comprising means for associating a cooling gas control system with said crucible and said heating control system for locally controlling the cooling of said silicon melt.

35. The system of claim 33, wherein said rate controlling means further comprises means for controlling the rate of using said gas cooling system in association with said heating control system.

36. The system of claim 33, wherein said rate controlling means further comprises means for controlling the rate of using said heating control system.

37. The system of claim 33, wherein said rate controlling means further comprises means for controlling the rate of using said heating control system, said heating control system comprising a plurality of separably controllable heaters.

38. The system of claim 30, wherein said rate controlling means further comprises means at least one argon or helium gas pathway for directing argon or helium cooling gas to predetermined regions of said crucible.

39. The system of claim 30, wherein said rate controlling means further comprises an array of argon or helium gas pathways for selectively and controllably directing argon or helium cooling gas to predetermined regions of said crucible.

40. The system of claim 30, wherein said crucible comprises an essentially cylindrical crucible, said essentially cylindrical crucible comprising a region wherein silicon crystallization may be initially formed using separably controllable ones of said heating elements.

41. The system of claim 30, wherein said crucible comprises an essentially quadratic crucible, said quadratic crucible comprising a region wherein silicon crystallization may be initially formed using separably controllable ones of said heating elements.
